(19) United States
(12) Patent Application Publication
(10) Pub. No.: US 2019/0393071 A1
(43) Pub. Date: Dec. 26, 2019

(54) CLEANING SECTION TRANSFER ROBOT FOR TRANSFERRING SUBSTRATE, SUBSTRATE PROCESSING APPARATUS, AND SUBSTRATE TRANSFER METHOD

(71) Applicant: EBARA CORPORATION, Tokyo (JP)

(72) Inventor: Junji KUNISAWA, Tokyo (JP)

(21) Appl. No.: 16/451,442

(22) Filed: Jun. 25, 2019

(30) Foreign Application Priority Data
Jun. 26, 2018 (JP) 2018-120909

(51) Int. Cl. H01L 21/687; B24B 37/34; H01L 21/67; H01L 21/677

(52) U.S. Cl. CPC H01L 21/68707; B24B 37/345; H01L 21/67706; H01L 21/6704; H01L 21/67219

(57) ABSTRACT

A cleaning section transfer robot includes a base, a rotary table, a first motor, a first substrate transfer mechanism including a second motor having a common rotation axis with the first motor, a first arm, a third motor, a second arm, a fourth motor, and a first hand, and a second substrate transfer mechanism including a fifth motor having a common rotation axis with the first motor, a third arm, a sixth motor, a fourth arm, a seventh motor, and a second hand. Each of the first arm, the second arm, the third arm, the fourth arm, the first hand, and the second hand extends in a direction perpendicular to the rotation axis of the first motor, and each of the third motor, the fourth motor, the sixth motor, and the seventh motor has a rotation axis parallel to the rotation axis of the first motor.

### CROSS-REFERENCE TO RELATED APPLICATIONS

This application is based on and claims priority from Japanese Patent Application No. 2018-120909, filed on Jun. 26, 2018, with the Japan Patent Office, the disclosure of which is incorporated herein in their entireties by reference.

### TECHNICAL FIELD

The present disclosure relates to a cleaning section transfer robot for transferring a substrate, a substrate processing apparatus, and a substrate transfer method.

### BACKGROUND

A chemical mechanical polishing (CMP) device for polishing the surface of a substrate has been known. A general CMP device includes a polishing table to which a polishing pad is attached and a top ring (also referred to as a polishing head) to which a substrate is mounted. A polishing liquid is supplied to the polishing pad. The general CMP device presses the substrate against the polishing pad and polishes the substrate by rotating at least one of the polishing table and the top ring, more particularly, by rotating both of the polishing table and top ring.

By polishing with the CMP device, a foreign substance such as abrasive particles in the polishing liquid may adhere to the substrate. The foreign substance adhering to the substrate may cause, tor example, defects in the substrate. Thus, the foreign substance adhering to the substrate may be removed after polishing the substrate. Therefore, a substrate processing apparatus provided with both a polishing section and a substrate cleaning section has been known.

An example of the substrate processing apparatus is illustrated in FIG. 1. FIG. 1 is a top view schematically illustrating a substrate processing apparatus 100. The substrate processing apparatus 100 of FIG. 1 includes a loading/unloading section 110, a polishing section 120, and a wafer station 130 (“WS” in the drawing). The substrate processing apparatus 100 further includes a substrate transfer unit 140, a substrate cleaning section 150, and a controller 160. The loading/unloading section 110 may include a FOUP 111 and a transfer robot 112 of lite loading/unloading section. The polishing section 120 may include a first polishing device 121, a second polishing device 122, a third polishing device 123, and a fourth polishing device 124 teach illustrated as “POS A to POS D” in the drawing) The substrate cleaning section 150 may include a first cleaning module 151, a second cleaning module 152, and a third cleaning module 153 (each illustrated as “CL1 to CL3” in the drawing). The substrate is cleaned multiple times from the first cleaning module 151 to the third cleaning module 153. The substrate cleaning section 150 may further include a first cleaning section transfer robot 154 and a second cleaning section transfer robot 155. The substrate processing apparatus 100 may include a plurality of substrate cleaning sections 150.

In the substrate processing apparatus 100 of FIG. 1, the first cleaning section transfer robot 154 receives a polished substrate from the wafer station 130 and transfers the received substrate to the first cleaning module 151 In addition, the first cleaning section transfer robot 154 receives the substrate cleaned by the first cleaning module 151, and transfers the received substrate to the second cleaning module 152. The second cleaning section transfer robot 155 receives the substrate cleaned by the second cleaning module 152, and transfers the received substrate to the third cleaning module 153.

The first cleaning section transfer robot 154 handles both a substrate after polishing and before cleaning and a substrate cleaned by the first cleaning module 151. Thus, the first cleaning section transfer robot 154 may be configured to prevent a polishing liquid from adhering to the polished substrate from moving to the substrate cleaned by the first cleaning module 151. Therefore, the first cleaning section transfer robot 154 may include at feast two hands. With the provision of at least two hands, the substrate after polishing and before cleaning and the substrate after cleaning may be transferred by separate hands.

### SUMMARY

In order to efficiently transfer a substrate, the hands of the cleaning section transfer robot may be able to operate independently of each other. However, since the space in the substrate processing apparatus 100 is limited, the hands may not be configured so as to be able to operate independently of each other. Therefore, it is an object of the present application to provide a progressive cleaning section transfer robot which is able to operate hands independently of each other within a limited space.

The present application discloses, as one embodiment, a cleaning section transfer robot for transferring a substrate to and from a cleaning module of a substrate cleaning section of a substrate processing apparatus, the cleaning section transfer robot including a base, a rotary table provided on the base, a first motor configured to rotate the rotary table, a first substrate holding mechanism, as a first substrate transfer mechanism, the first substrate holding mechanism including a second motor provided on the rotary table and having a common rotation axis with the first motor, a first arm connected to the second motor, a third motor provided on a tip end of the first arm, a second arm connected to the third motor, a fourth motor provided on a tip end of the second arm, and a first hand connected to the fourth motor to hold the substrate, and a second substrate holding mechanism, as a second substrate transfer mechanism, the second substrate holding mechanism including a fifth motor provided on the first arm and having a common rotation axis with the first motor, a third arm connected to the fifth motor, a sixth motor provided on a tip end of the third arm, a fourth arm connected the sixth motor, a seventh motor provided on a tip end of the fourth arm, and a second hand connected to the seventh motor to hold the substrate, wherein each of the first arm, the second arm, the third arm, the fourth arm, the first hand, and the second hand extends in a direction perpendicular to the rotation axis of the first motor, and wherein each of the third motor, the fourth motor, the sixth motor, and the seventh motor has a rotation axis parallel to the rotation axis of the first motor.

The foregoing summary is illustrative only and is not intended to be in any way limiting. In addition to the illustrative aspects, embodiments, and features described above, further aspects, embodiments, and features will become apparent by reference to the drawings and the following detailed description

### BRIEF DESCRIPTION OF THE DRAWINGS

FIG. 1 is a top view schematically illustrating a substrate processing apparatus.

FIG. 2A is a top view of a cleaning section transfer robot.

FIG. 2B is a front view of the cleaning section transfer robot of FIG. 2A.

FIG. 3 is a front view of a cleaning section transfer robot according to a comparative example.

FIG. 4 is a front view of a cleaning section transfer robot including a sensor and a tray.

FIG. 5A is a view illustrating a first step (hereinafter simply referred to as “the xth step”) of a method of transferring a substrate from a wafer station to a first cleaning module and from the first cleaning module to a second cleaning module using the cleaning section transfer robot of FIGS. 2A and 2B.

FIG. 5B is a view illustrating a second step following the first step illustrated in FIG. 5A.

FIG. 5C is a view illustrating a third step following the second step illustrated in FIG. 5B.

FIG. 5D is a view illustrating a fourth step following the third step illustrated in FIG. 5C.

FIG. 5E is a view illustrating a fifth step following the fourth step illustrated in FIG. 5D.

FIG. 5F is a view illustrating a sixth step following the fifth step illustrated in FIG. 5E.

FIG. 5G is a view illustrating a seventh step following the sixth step illustrated in FIG. 5F.

FIG. 5H is a view illustrating an eighth step following the seventh step illustrated in FIG. 5G.

FIG. 5I is a view illustrating a ninth step following the eighth step illustrated in FIG. 5H.

FIG. 5J is a view illustrating a tenth step following the ninth step illustrated in FIG. 5I.

FIG. 5K is a view illustrating an eleventh step following the tenth step illustrated in FIG. 5J.

FIG. 5L is a view illustrating a twelfth step following the eleventh step illustrated in FIG. 5K.

FIG. 6A is a view illustrating a first cleaning module in which a substrate is accommodated, and a first cleaning section transfer robot.

FIG. 6B is a view illustrating a state where a second hand of the first cleaning section transfer robot of FIG. 6A receives the substrate accommodated in the first cleaning module.

FIG. 6C is a view illustrating a state where a second substrate transfer mechanism is folded after FIG. 6D.

FIG. 7 is a view illustrating a filter fan unit and the first cleaning section transfer robot.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

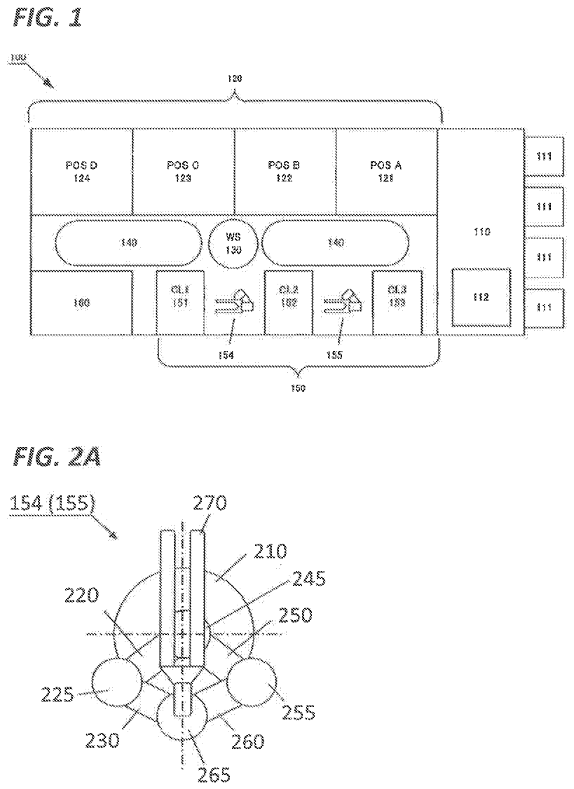

The substrate processing apparatus 100 according to one embodiment of the present application has substantially the same configuration as that of FIG. 1 except for progressive improvement. However, it is to be noted that FIG. 1 is only a schematic view. For example, an actual substrate processing apparatus may have a shape different from that of FIG. 1. For example, an actual substrate processing apparatus may include elements not illustrated in FIG. 1.

The loading/unloading section 110 is provided to load a substrate which needs to be processed from the outside of the substrate processing apparatus 100 and to unload the substrate which has been completely processed from the inside of the substrate processing apparatus 100. The substrate may be a silicon wafer or any other type of substrate. The loading/unloading section 110 included at least one (four in the illustrated example) FOUP 111 and the transfer robot 112 of the loading/unloading section. The FOUP 111 may accommodate a substrate or a substrate cassette in which the substrate is accommodated. The transfer robot 112 of the loading/unloading section receives or delivers the substrate from or to the desired FOUP 111. The substrate received by the transfer robot 112 of the loading/unloading section may be sent to the polishing section 120 by the substrate transfer unit 140 to be described later and/or a mechanism (not illustrated).

The polishing section 120 in the example of FIG. 1 includes the first polishing device 121, the second polishing device 122, the third polishing device 123, and the fourth polishing device 124. Here, the terms such as “first” and “second” used in describing the polishing device are merely terms for distinguishing the components of the substrate processing apparatus 100. In other words, the terms such as “first” and “second” used in describing the polishing device may be unrelated to the order of polishing, or may be related to the order of polishing.

Each of the first polishing device 121 to the fourth polishing device 124 is, for example, a CMP device. Each of the first polishing device 121 to the fourth polishing device 124 includes a polishing table (not illustrated) for attachment of a polishing pad and a top ring (not illustrated) for attachment of a substrate. However, each of the first polishing device 121 to the fourth polishing device 124 may be a CMP device having another configuration, or may be a polishing device other than the CMP device. Each of the first polishing device 121 to the fourth polishing device 124 may be provided with a liquid supply device (not illustrated) for supplying, for example, a polishing liquid to the polishing pad. The liquid supply device may be separately provided for each of the first polishing device 121 to the fourth polishing device 124. One liquid supply device may be configured to supply a liquid to a plurality of polishing devices.

The substrate polished by the polishing section 120 is transferred to the wafer station 130. The wafer station 130 is configured to be able to hold a substrate after being polished and before being cleaned The wafer station 130 may be able to hold one substrate, or may be able to hold two or more substrates. The substrate transfer unit 140 is configured to transfer a substrate from the polishing section 120 to the wafer station 130. In addition, as described above, the substrate transfer unit 140 may be in charge of at least a part of substrate transfer between the loading/unloading section 110 and the polishing section 120.

The substrate held by the wafer station 130 is transferred to the substrate cleaning section 150. The transfer of the substrate between the wafer station 130 and the substrate cleaning section 150 is performed by the first cleaning section transfer robot 154. The substrate transferred to the substrate cleaning section 150 is cleaned by each cleaning module (the first cleaning module 151, the second cleaning module 152, or the third cleaning module 153). More specifically, a cleaner (not illustrated) provided in each cleaning module may be configured to clean the substrate. In addition, the cleaning module (the third cleaning module 153 in the example of FIG. 1) in charge of a final process of cleaning may have a function of drying the substrate, for example, a function of rotating the substrate at a high speed (spin dry function). Additionally or alternatively, a drying module may be provided at a trailing end of the third cleaning module 153. In addition, the number of cleaning modules provided in the substrate cleaning section 150 is not limited to three. The number of cleaning modules may be one, two, or four or more. For example, the number and/or placement of cleaning section transfer robots may also be changed according to for example, the number and/or placement of cleaning modules.

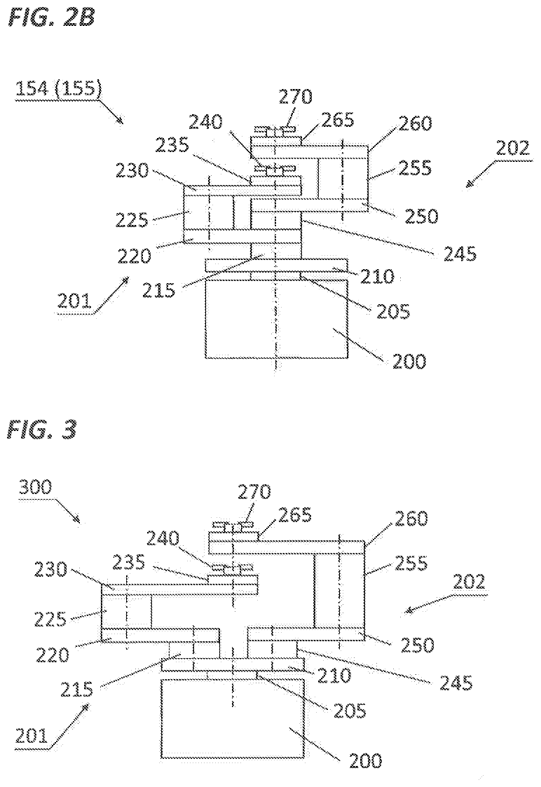

FIGS. 2A and 2B illustrate a cleaning section transfer robot according to one embodiment. Hereinafter, the cleaning section transfer robot illustrated in FIGS. 2A and 2B will be described as the first cleaning section transfer robot 154. However, the second cleaning section transfer robot 155 may be configured as illustrated in FIGS. 2A and 2B. FIG. 2A is a top view of the first cleaning section transfer robot 154 FIG. 2B is a front view of the first cleaning section transfer robot 154. The first cleaning section transfer robot 154 of FIGS 2A and 2B includes a base 200 and a rotary table 210 located on the base 200. A first motor 205 is provided between the base 200 and the rotary table 210. The first motor 205 is able to rotate the rotary table 210.

The first cleaning section transfer robot 154 includes a first substrate transfer mechanism 201 and a second substrate transfer mechanism 202. The first substrate transfer mechanism 201 includes a second motor 215, a first arm 220, a third motor 225, a second arm 230, a fourth motor 235, and a first hand 240. The second substrate transfer mechanism 202 includes a fifth motor 245, a third arm 250, a sixth motor 255, a fourth arm 260, a seventh motor 265, and a second hand 270.

The second motor 215 for the first arm 220 is provided on the top of the center of the rotary table 210. The rotation axis of the second motor 215 is common to the rotation axis of the first motor 205. However, the expression “the rotation axis is common” referred to here means that “an imaginary rotation axis is common”, in other words, that “the extension line of each motor axis is on the same straight line (within the range of acceptable errors such as design errors, mounting errors, and manufacturing errors)”, and does not necessarily mean that “a rotation shaft as a mechanical part is shared”. The first arm 220 is connected to the second motor 215. The first arm 220 is rotated by the second motor 215.

The third motor 225 for the second arm 230 is provided on the top of the tip end of the first arm 220. The second arm 230 is connected to the third motor 225. The lengths of the first arm 220 and the second arm 230 may be determined according to the position at which the first hand 240 is to receive or deliver the substrate. The length of the second arm 230 may be substantially the same as the length of the first arm 220.

The fourth motor 235 for the first hand 240 is provided on the top of the tip end of the second arm 230. The first hand 240 is connected to the fourth motor 235. The first hand 240 is a member for holding a substrate. The first hand 240 is used, for example, to transfer a substrate from the first cleaning module 151 to the second cleaning module 152. The rotation of the first hand 240 by the fourth motor 235 may change the orientation of the first hand 240 with respect to the second arm 230. In addition, as best seen in FIG. 2B, the cooperation of the second motor 215, the third motor 225, and the fourth motor 235 allows the first substrate transfer mechanism 201 to be folded. On the other hand, the cooperation of the second motor 215, the third motor 225, and the fourth motor 235 allows the first substrate transfer mechanism 201 to be deployed in any direction.

The fifth motor 245 for the third arm 250 is provided on the top of the root of the first arm 220. The rotation axis of the fifth motor 245 is common to the rotation axis of the first motor 205. The third arm 250 is connected to the fifth motor 245. The third arm 250 is rotated by the fifth motor 245. In addition, in the configuration illustrated in FIG. 2, since the third arm 250 is located above the second motor 215, the rotational force generated by the second motor 215 is transmitted to the third arm 250. Thus, the third arm 250 is rotated by the second motor 215 as well as the fifth motor 245. The rotation of the third arm 250 by the second motor 215 may be offset by the fifth motor 245. Alternatively, the first cleaning section transfer robot 154 may be configured such that the rotational force generated by the second motor 215 is not transmitted to the third arm 250.

The sixth motor 255 for the fourth arm 260 is provided on the top of the tip end of the third arm 250. The fourth arm 260 is connected to the sixth motor 255. The lengths of the third arm 250 and the fourth arm 260 may be determined according to the position at which the second hand 270 is to receive or deliver a substrate. The length of the third arm 250 may be substantially the same as the length of the fourth arm 260. In one embodiment, the lengths of the first arm 220, the second arm 230, the third arm 250, and the fourth arm 260 are substantially the same. However, the expression “the length of the arm” referred to here may be literally the length of the arm, or may be an effective length of the arm. The expression “the effective length of the arm” referred to here means the length of the arm between the rotation axis of the motor provided on the root of each arm and the rotation axis of the motor provided on the lip end of each arm. On the other hand, the lengths of the respective arms are not necessarily the same according to the specification required for the apparatus.

The seventh motor 265 for the second hand 270 is provided on the top of the tip end of the fourth arm 260. The second hand 270 is connected to the seventh motor 265. The second hand 270 is a member for holding a substrate. The second hand 270 is used, for example, to transfer a substrate from the wafer station 130 to the first cleaning module 151. However, the roles of the first hand 240 and the second hand 270 may be switched. The seventh motor 265 may rotate the second hand 270 to change the orientation of the second hand 270 with respect to the fourth arm 260. In addition, an best seen in FIG. 2B, the cooperation of the fifth motor 245, the sixth motor 255, and the seventh motor 265 allows the second substrate transfer mechanism 202 to be folded. On the other hand, the cooperation of the fifth motor 245, the sixth motor 255, and the seventh motor 265 allows the second substrate transfer mechanism 202 to be deployed in any direction.

Each of the first arm 220, the second arm 230, the third arm 250, the fourth arm 260, the first hand 240, and the second hand 270 extends in a direction perpendicular to the rotation axis of the first motor 205 (usually in the horizontal direction). In addition, each of the third motor 225, the fourth motor 235, the sixth motor 255, and the seventh motor 265 has a relation axis parallel to the rotation axis of the first motor 205. In addition, as described above, the second motor 215 and the fifth motor 245 have a common rotation axis with the first motor 205. Thus, the respective rotation axes of the second motor 215 and the fifth motor 245 are naturally parallel to the rotation axis of the first motor 205.

The first cleaning section transfer robot 154 is configured such that collision between parts does not occur when the first substrate transfer mechanism 201 and/or the second substrate transfer mechanism 202 is folded. In other words, the positions of the fifth motor 245 and the third arm 250 in the direction along the rotation axis of the first motor 205 (usually the positions in the height direction) are between the position of the first arm 220 in the direction along the rotation axis of the first motor 205 and the position of the second arm 230 in the direction along the rotation axis of the first motor 205. In addition, the positions of the second arm 230, the fourth motor 235, and the first hand 240 in the direction along the rotation axis of the first motor 205 are between the position of the third arm 250 in the direction along the rotation axis of the first motor 205 and the position of the fourth arm 260 in the direction along the rotation axis of the first motor 205.

At least one of the first motor 205 to the seventh motor 265 may be a hollow shaft motor to allow wiring used for the first cleaning section transfer robot 154 to pass therethrough. In addition, since the first cleaning section transfer robot 154 is used to clean a substrate, the first cleaning section transfer robot 154 has at least one of a dustproof function and a waterproof function. Moreover, the first cleaning section transfer robot 154 may be exposed to a polishing liquid used by the polishing section 120 and a chemical liquid such as a cleaning liquid used by the substrate cleaning section 150. Therefore, at least a portion of the first cleaning section transfer robot 154 is formed of a material having chemical resistance, or chemical resistant coating is performed on at least a portion of the first cleaning section transfer robot 154.

Each motor in FIGS. 2A and 2B is controlled by the controller 160. Control of each motor by the controller 160 enables the first hand 240 and the second hand 270 to operate independently of each other. By using the motor instead of a pulley, for example, as an element for rotating each arm and each hand, a free operation of each arm and each hand is possible.

The rotation axis of the fifth motor 245 in the first cleaning section transfer robot 154 in FIGS. 2A and 2B is common to the rotation axis of the first motor 205. That is, in FIGS. 2A and 2B, it can be said that the second substrate transfer mechanism 202 is placed on the first substrate transfer mechanism 201. Thus, the space in the horizontal plane occupied by the first cleaning section transfer robot 154 in FIGS. 2A and 2B is smaller than the space in the horizontal plane occupied by the cleaning section transfer robot (the cleaning section transfer robot 300 in FIG. 3) in which the second motor 215 and the fifth motor 245 are horizontally arranged on the rotary table 210.

As described above, the cleaning section transfer robot according to one embodiment may be able to operate the hands independently of each other, and may reduce the space occupied by the first cleaning section transfer robot 154. In addition, it is to be noted that the configuration of FIGS. 2A and 2B is merely illustrative. For example, a third substrate transfer mechanism may further be provided above the third arm 250. For example, the fourth motor 235 and the first hand 240 may be provided on the lower surface of the second arm 230. For example, a mechanism that moves each part up and down may further be provided.

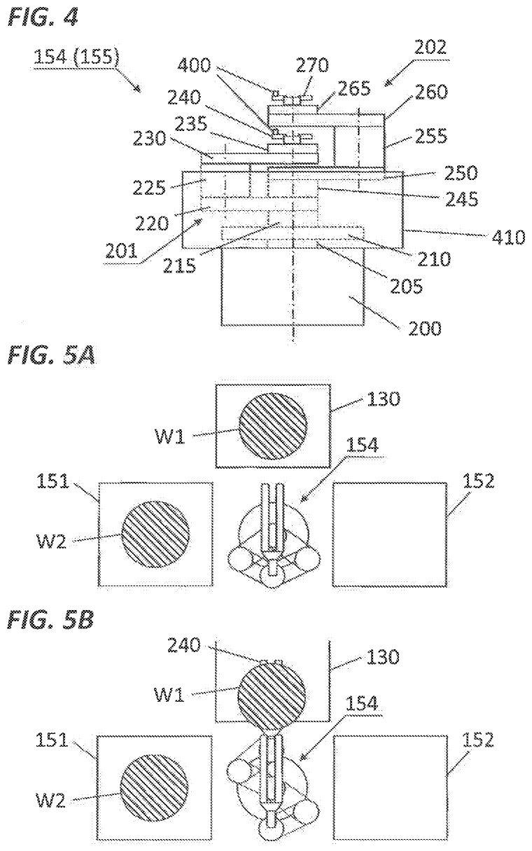

Next, a modification of the first cleaning section transfer robot 154 will be described with reference to FIG. 4. The first cleaning section transfer robot 154 in FIG. 4 is provided with a sensor 400 which detects the presence or absence of a substrate on the first hand 240 and the second hand 270. In the configuration of FIG. 4, one sensor 400 is provided on the first hand 240, and the other sensor 400 is provided on the second hand 270. However, as long as the presence or absence of a substrate may be detected, the position and the number of sensors 400 do not matter. The sensor 400 may be, for example, an optical sensor, a weight sensor, a micro switch, or any other sensor By checking the presence or absence of a substrate on each hand by the sensor 400, it is possible to prevent a failure in the transfer of the substrate.

In the typical substrate processing apparatus 100, the first cleaning section transfer robot 154 is placed in a “wet” environment, i.e., an environment in which a liquid such as a polishing liquid or a cleaning liquid may be present. Therefore, the first cleaning section transfer robot 154 may further include a tray 410 for accommodating a liquid. The tray 410 in FIG. 4 is provided on the top of the base 200 and is configured to accommodate a liquid which drops or scatters from each element of the first cleaning section transfer robot 154 such as the first hand 240 or the second hand 270. By providing the tray 410, it is possible to prevent the liquid dropped from each element of the first cleaning section transfer robot 154 from dropping on the floor surface of the substrate processing apparatus 100. In addition, the shape of the bay 410 may be appropriately determined according to desired performance. A drain line (not illustrated) may be connected to the tray 410.

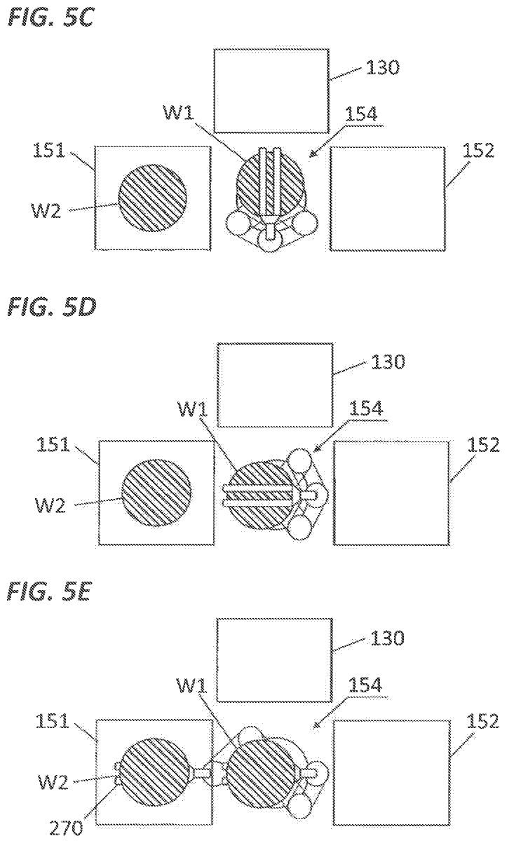

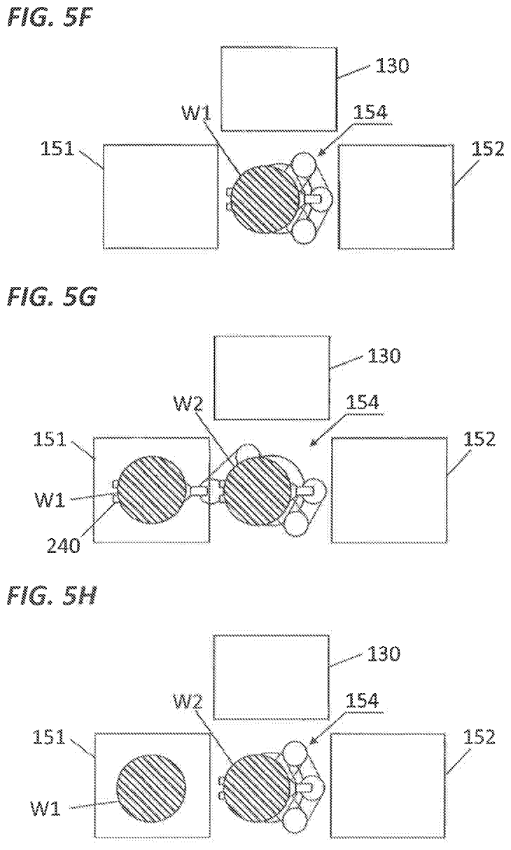

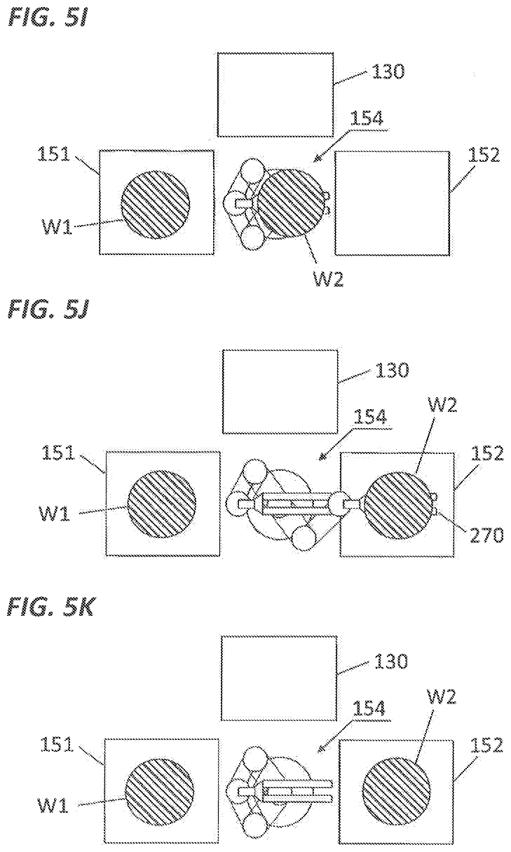

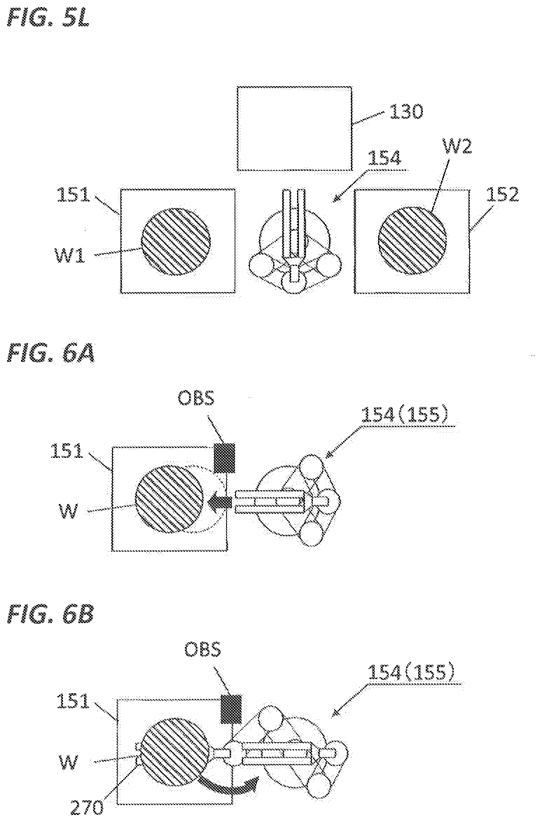

Next, an efficient substrate transfer method using the first cleaning section transfer robot 154 according to one embodiment will be described with reference to FIGS. 5A to 5L. The elements of the first cleaning section transfer robot 154 are not designated by reference numerals in FIGS. 5A to 5L except as particularly useful for the description. In addition, the hatching applied to the substrate in FIGS. 5A to 5L is merely provided to distinguish the substrate from other elements. Thus, the hatching in FIGS. 5A to 5L does not mean a cross section. Herein, a description related to a situation in which a polished substrate W1 is accommodated in the wafer station 130, the other substrate W2 is accommodated in the first cleaning module 151, and no substrate is accommodated in the second cleaning module 152 is disclosed. However, when transferring a substrate using the first cleaning section transfer robot 154, it is not always necessary to start the transfer from this situation.

FIG. 5A is a view illustrating a first step (hereinafter simply referred to as “the xth step”) of a method of transferring a substrate from the wafer station 130 to the first cleaning module 151 and from the first cleaning module 151 to the second cleaning module 152 using the first cleaning section transfer robot 154 according to one embodiment. In FIG. 5A, the substrate W1 is accommodated in the wafer station 130, and the other substrate W2 is accommodated in the first cleaning module 151.

FIG. 5B is a view illustrating a second step. The controller 160 controls the second motor 215, the third motor 225, and the fourth motor 235 so that the first hand 240 moves to the inside of the wafer station 130. The controller 160 may synchronously control the second motor 215, the third motor 225, and the fourth motor 235 so that the first hand 240 linearly moves toward the wafer station 130. In addition, a description related to the linear motion of each hand is omitted below. The controller 160 may control the fifth motor 245 to offset rotation which may occur in the third arm 250. In addition, a description related to the offset of rotation which may occur in the third arm 250 is omitted below. In an embodiment, the controller 160 performs control of the second step when it is predicted that the first cleaning module 151 completely cleans the substrate W2. The first hand 240 receives the substrate W1 in the wafer station 130.

FIG. 5C is a view illustrating a third step. The controller 160 controls the second motor 215, the third motor 225, and the fourth motor 235 so that the first substrate transfer mechanism 201 is folded.

FIG. 5D is a view illustrating a fourth step. The controller 160 controls the first motor 205 so that the first hand 240 and the second hand 270 face the first cleaning module 151. After change in the orientation of the hand is completed, the controller 160 stands by until the cleaning of the substrate W2 by the first cleaning module 151 is completed.

FIG. 5E is a view illustrating a fifth step. The controller 160 which has received an instruction that “the cleaning of the substrate W2 by the first cleaning module 151 is completed” or has detected that the cleaning of the substrate W2 by the first cleaning module 151 has been completed by a certain device controls the fifth motor 245, the sixth motor 255, and the seventh motor 265 so that the second band 270 moves to the inside of the first cleaning module 151. The second hand 270 receives the cleaned substrate W2 in the first cleaning module 151.

FIG. 5F is a view illustrating a sixth step. The controller 160 controls the fifth motor 245, the sixth motor 255, and the seventh motor 265 so that the second substrate transfer mechanism 202 is folded. In addition, in FIG. 5F. the substrate W2 is invisible by the substrate W1.

FIG. 5G is a view illustrating a seventh step. The controller 160 controls the second motor 215, the third motor 225, and the fourth motor 235 so that the first hand 240 moves to the inside of the first cleaning module 151. It is to be noted that FIG. 5G is very similar to FIG. 5E but the hand moving to the inside of the first cleaning module 151 is the first hand 240 rather than the second hand 270. The first hand 240 delivers the polished (undefined) substrate W1 to the first cleaning module 151. The first cleaning module 151 which has received the substrate W1 starts to clean the substrate W1.

FIG. 5H is a view illustrating an eighth step. The controller 160 controls the second motor 215, the third motor 225, and the fourth motor 235 so that the first substrate transfer mechanism 201 is folded. It is to be noted that FIG. 5H is somewhat similar to FIG. 50 but the hand holding the substrate in FIG. 5H is the second hand 270 rather than the first hand 240. In addition, it is also to be noted that the substrate held by the second hand 270 in FIG. 5H is the substrate W2 cleaned by the first cleaning module 151.

FIG. 5I is a view illustrating a ninth step. The controller 160 controls the first motor 205 so that the first hand 240 and the second hand 270 face the second cleaning module 152.

FIG. 5J is a view illustrating a tenth step. The controller 160 controls the fifth motor 245, the sixth motor 255, and the seventh motor 265 such that the second hand 270 moves to the inside of the second cleaning module 152. The second hand 270 delivers the substrate W2 to the second cleaning module 152. The second cleaning module 152 which has received the substrate W2 starts to further clean the substrate W2.

FIG. 5K is a view illustrating an eleventh step. The controller 160 controls the fifth motor 245, the sixth motor 255, and the seventh motor 265 so that the second substrate transfer mechanism 202 is folded.

FIG. 5L is a view illustrating a twelfth step. The controller 160 controls the first motor 205 so that the first hand 240 and the second hand 270 face the wafer station 130. After the twelfth step, when the cleaning of the substrate W2 is completed, the second cleaning section transfer robot 155 (see FIG. 1) transfers the substrate W2. After the substrate W2 is carried out from the second cleaning module 152, when a new substrate is transferred to the wafer station 130, the controller 160 returns to FIG. 5A to control the first cleaning section transfer robot 154.

As described above with reference to FIGS. 5A to 5L, since the first cleaning section transfer robot 154 according to one embodiment is able to operate at least two hands independently of each other, it is possible to transfer another substrate while any substrate is cleaned. Thus, the first cleaning section transfer robot 154 according to one embodiment is more advantageous in terms of throughput as compared to both a robot having only a single hand and a robot that may not operate a plurality of hands independently of each other.

In addition, the transfer method of FIGS. 5A to 5L is merely an example for illustrating the superiority of the first cleaning section transfer robot 154 according to one embodiment. When actually transferring a substrate, a method other than the method illustrated in FIGS. 5A to 5L may be executed.

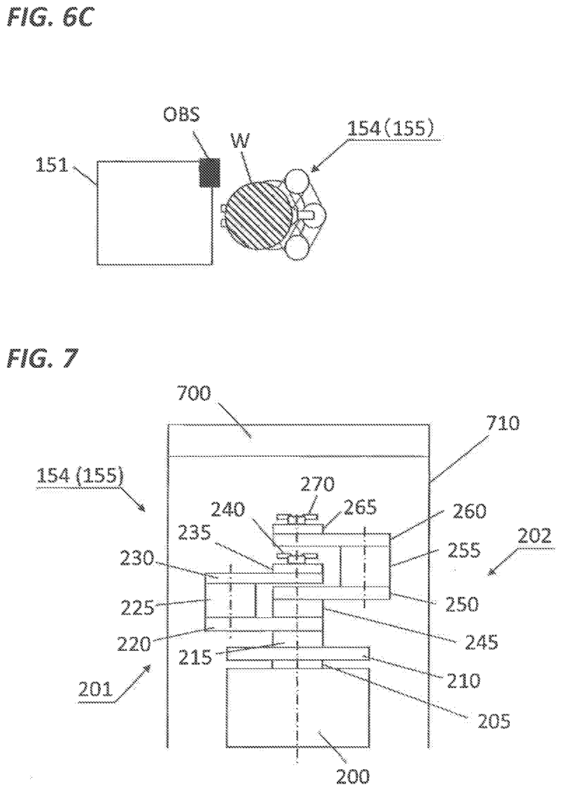

There may be an obstacle “OBS” near the transfer robot according to a structure of the substrate processing apparatus 100. The object that may be the obstacle OBS may include, for example, a wall, a column, and other parts of the substrate processing apparatus 100. Since the space inside the substrate processing apparatus 100 is limited, it may be difficult to adopt a configuration in which no obstacle exists. Hereinafter, a method of transferring a substrate while avoiding the obstacle OBS will be described with reference to FIGS. 6A to 6C. Although the first cleaning section transfer robot 154 is used in FIGS. 6A to 6C, the second cleaning section transfer robot 155 may be used. The first cleaning module 151 in which the substrate W is accommodated and the first cleaning section transfer robot 154 are illustrated in FIG. 6A. FIG. 6B illustrates a state where the second hand 270 of the first cleaning section transfer robot 154 of FIG. 6A receives the substrate W accommodated in the first cleaning module 151. FIG. 6C illustrates a state where the second substrate transfer mechanism 202 is folded after FIG. 6B.

In FIGS. 6A to 6C, it is assumed that there is the obstacle OBS in a portion of the first cleaning module 151 (in the upper right direction in FIGS. 6A to 6C). As illustrated by an imaginary line in FIG. 6A. when assuming that the substrate W linearly moves toward the first cleaning section transfer robot 154, the substrate W collides with the obstacle OBS. Thus, it is necessary to avoid the obstacle OBS when transferring the substrate W. On the other hand, the width of the hand of the first cleaning section transfer robot 154 is smaller than the diameter of the substrate W. Thus, it is not necessary to avoid the obstacle OBS when the hand not holding the substrate W (which is the second hand 270 in the example of FIGS. 6A to 6C but may be the first hand 240 instead of the second hand 270) moves to the inside of the first cleaning module 151. Therefore, the controller controls the substrate processing apparatus 100 to move the second hand 270 not holding the substrate W to the inside of the first cleaning module 151 in which the substrate W is accommodated by linear movement (see the arrow of FIG. 6A and in addition, a target to be controlled here is specifically the first cleaning section transfer robot 154 or the second cleaning section transfer robot 155, and more specifically, each motor of these robots). Since linear movement has the shortest movement distance, the time required for the movement is also advantageously short.

Next, the controller 160 controls the substrate processing apparatus 100 to receive the substrate W accommodated in the first cleaning module 151 by the second hand 270.

As described above, since the substrate W and the obstacle OBS may collide with each other, it is impossible to transfer the substrate W to the outside of the first cleaning module 151 by linear movement. Therefore, the controller 160 controls the substrate processing apparatus 100 to fold the second substrate transfer mechanism 202 while driving the first motor 205 so that the substrate W passes through a track away from the obstacle OBS (see the arrow of FIG. 6B). In addition, when the first hand 240 is used instead of the second hand 270, an object to be folded is the first substrate transfer mechanism 201. During this control, whether or not each hand receives the substrate W may be detected by the sensor 400 (see FIG. 4).

The rotation of the arm or the hand in the first cleaning section transfer robot 154 according to one embodiment is performed by a motor rather than a pulley. Thus, the first cleaning section transfer robot 154 according to one embodiment may lake a complicated behavior as described in FIGS. 6A to 6C. By the above operation, even when the obstacle OBS exists due to the limitation of the space inside the substrate processing apparatus 100, the substrate W may be transferred from the first cleaning module 151, for example (see FIG. 6C). A specific operation of the first cleaning section transfer robot 154 may differ according to, for example, the position, the size, the number, or the shape of the obstacle OBS. The position, the size, the number, or the shape of the obstacle OBS, for example, varies according to a configuration of the substrate processing apparatus 100. Then, the configuration of the substrate processing apparatus 100 is determined at the time of designing the apparatus. Thus, a specific operation for avoiding the obstacle OBS may be determined based on design data of the substrate processing apparatus 100.

In FIGS. 6A to 6C, the substrate W is accommodated in the first cleaning module 151. However, the concept described in FIGS. 6A to 6C may be used when transferring the substrate W accommodated in any of the wafer station 130, the second cleaning module 152, and the third cleaning module 153. More generally, the concept described in FIGS. 6A to 6C may be used when transferring the substrate W accommodated in any object that is accessible by the cleaning section transfer robot. In addition, when the substrate is transferred to, for example, a cleaning module having an obstacle by the hand holding the substrate, the concept of FIGS. 6A to 6C may be used in the reverse order of FIGS. 6A to 6C. That is, the controller 160 may control the substrate processing apparatus 100 to execute the steps of:
moving the first hand 240 or the second hand 270 not holding the substrate while driving the first motor 205 to die inside of the cleaning module or to the inside of the wafer station 130 so that the substrate passes through a track away from the obstacle OBS.
delivering the substrate from the first hand 240 or the second hand 270; and
folding the first substrate transfer mechanism 201 or the second substrate transfer mechanism 202 so that the first hand 240 or the second hand 270 linearly moves.

In an embodiment, a downward airflow (downflow) may be blown around the cleaning section transfer robot. FIG. 7 is a view illustrating a filter fan unit 700. In FIG. 7, the first cleaning section transfer robot 154 is illustrated as a representative. The filter fan unit 700 blows clean gas (typically air) from the top to the bottom of the first cleaning section transfer robot 154. That filter fan unit 700 may cover the first cleaning section transfer robot 154. That is, the filter fan unit 700 may act as a housing 710 of the first cleaning section transfer robot 154. In other words, the filter fan unit 700 and the housing 710 may be integrated with each other. On the other hand, the filter fan unit 700 may be attached to the housing 710 of the first cleaning section transfer robot 154. In other words, the filter fan unit 700 and the housing 710 may be independent elements. In addition, the column or the wall surface of the substrate processing apparatus 100 may be regarded as the housing 710 of the first cleaning section transfer robot 154. The inside of the housing 710 may beat a positive pressure as compared with the outside of the substrate processing apparatus 100.

In addition, in order to discharge the airflow from the filter fan unit 700, the bottom of the housing 710 is not sealed but is open. However, another configuration is possible, such as, for example, a configuration in which the gas is circulated in the housing 710. For convenience of illustration, FIG. 7 illustrates the housing 710 which covers only the first cleaning section transfer robot 154. As another example, all or some of the wafer station 130, the substrate transfer unit 140, the first cleaning section transfer robot 154. and the second cleaning section transfer robot 155 may be in the same space (within the same housing). When the first cleaning section transfer robot 154 includes the may 410, the substrate processing apparatus 100 is designed so that the housing 710 and the tray 410 do not interfere with each other. The tray 410 may be disposed inside the housing 710. In another example, the projection plane of the tray 410 in the horizontal plane is inside the projection plane of the housing 710 in the horizontal plane. A gap may be formed between the housing 710 and the tray 410 to discharge the airflow from the filter fan unit 700. In addition, an exhaust port for discharging the airflow may be formed in the housing 710. It is particularly advantageous to form the exhaust port in the housing 710 when the bottom of the housing 710 is not open or when no gap is formed between the housing 710 and the tray 410. However, the exhaust port may be formed in the housing 710 having the open bottom, or the gap and the exhaust port may be used together. In an exemplary form, the exhaust port is formed in the entirety or a part of the perimeter of the lowermost portion of the housing 710. However, the position of the exhaust port is not limited to the above-described position. The position of the exhaust port may be determined depending on, for example, a specific airflow, a required specification, or a relationship with another member.

By configuring the substrate processing apparatus 100, the cleaning section transfer robot (e.g., the first cleaning section transfer robot 154) and/or the filter fan unit 700 as described above, the periphery of the cleaning section transfer robot may be maintained in a clean environment. The filter fan unit 700 may be an element separate from other members, may be a portion of a robot such as the first cleaning section transfer robot 154, or may be a portion of the substrate processing apparatus 100.

Several embodiments of the present disclosure have been described above. The embodiments of the disclosure described above are for the purpose of facilitating the understanding of the present disclosure, and are not intended to limit the present disclosure. The present disclosure may be modified and improved without departing from the spirit of the present disclosure and, of course, includes the equivalents thereof. In addition, any combination or omission of each component described in the claims and the specification is possible within a range in which at least some of the above-mentioned subjects may be solved or within a range that exerts at least some of the effects.

The present application discloses, as one embodiment, a cleaning section transfer robot configured to transfer a substrate to a cleaning module of a substrate cleaning section of a substrate processing apparatus and to transfer the substrate from the cleaning module, the cleaning section transfer robot including a base, a rotary table provided on the base, a first motor configured to rotate the rotary table, a first substrate holding mechanism as a first substrate transfer mechanism, the first substrate holding mechanism including a second motor provided on the rotary table and having a common rotation axis with the first motor, a first arm connected to the second motor, a third motor provided on a tip end of the first arm, a second arm connected to the third motor, a fourth motor provided on a tip end of the second arm, and a first hand connected to the fourth motor to hold the substrate, and a second substrate holding mechanism as a second substrate transfer mechanism, the second substrate holding mechanism including a fifth motor provided on the first arm and having a common rotation axis with the first motor, a third arm connected to the fifth motor, a sixth motor provided on a tip end of the third arm, a fourth arm connected to the sixth motor, a seventh motor provided on a tip end of the fourth arm, and a second hand connected to the seventh motor to hold the substrate, wherein each of the first arm, the second arm, the third arm, the fourth arm, the first hand, and the second hand extends in a direction perpendicular to the rotation axis of the first motor, and wherein each of the third motor, the fourth motor, the sixth motor, and the seventh motor has a rotation axis parallel to the rotation axis of the first motor

In addition, the present application discloses, as one embodiment, a substrate processing apparatus including a polishing section configured to polish a substrate and a substrate cleaning section configured to clean the substrate polished by the polishing section, wherein the substrate cleaning section includes one or more cleaning modules and one or more cleaning section transfer robots configured to transfer the substrate to at least one of the one or more cleaning modules and to transfer the substrate from the at least one of the one or more cleaning modules, wherein the at least one of the one or more cleaning section transfer robots includes a base, a rotary table provided on the base, a first motor configured to rotate the rotary table, a first substrate holding mechanism as a first substrate transfer mechanism, the first substrate holding mechanism including a second motor provided on the rotary table and having a common rotation axis with the first motor, a first arm connected to the second motor, a third motor provided on a tip end of the first arm, a second arm connected to the third motor, a fourth motor provided on a tip end of the second arm, and a first hand connected to the fourth motor to hold the substrate, and a second substrate holding mechanism as a second substrate transfer mechanism, the second substrate holding mechanism including a fifth motor provided on the first arm and having a common rotation axis with the first motor, a third arm connected to the fifth motor, a sixth motor provided on a tip end of the third arm, a fourth arm connected to the sixth motor, a seventh motor provided on a tip end of the fourth arm, and a second hand connected to the seventh motor to hold the substrate, wherein each of the first arm, the second arm, the third arm, the fourth arm, the first hand, and the second hand extends in a direction perpendicular to the rotation axis of the first motor, and wherein each of the third motor, the fourth motor, the sixth motor, and the seventh motor has a rotation axis parallel to the rotation axis of the first motor.

The cleaning section transfer robot and the substrate processing apparatus described above have effects of being capable of operating the respective hands independently of each other and reducing the space occupied by the cleaning section transfer robot us an example.

Moreover, the present application discloses, as one embodiment, a cleaning section transfer robot in which respective lengths of the first arm, the second arm, the third arm, and the fourth arm are the same.

The disclosed content reveals details of each arm.

In addition, the present application discloses, as one embodiment, a cleaning section transfer robot in which positions of the fifth motor and the third arm in a direction along tire rotation axis of the first motor are between a position of the first arm in the direction along the rotation axis of the first motor and a position of the second arm in the direction along the rotation axis of the first motor, and positions of the second arm, the fourth motor, and the first hand in the direction along the rotation axis of the first motor are between the position of the third arm in the direction along the rotation axis of the first motor and a position of the fourth arm in the direction along the axis of rotation of the first motor.

The cleaning section transfer robot has an effect of being capable of preventing collision of each substrate transfer mechanism as an example.

In addition, the present application discloses, as one embodiment, a cleaning section transfer robot further including a sensor configured to detect presence or absence of the substrate on the first hand and the second hand.

The cleaning section transfer robot has an effect of being capable of preventing failure in transfer of the substrate as an example.

In addition, the present application discloses, as one embodiment, a cleaning section transfer robot further including a tray provided on the base to accommodate a liquid.

The cleaning section transfer robot has an effect of being capable of preventing dropping or scattering of the liquid from the cleaning section transfer robot as an example.

In addition, the present application discloses, as one embodiment, a cleaning section transfer robot in which at least one of the first motor, the second motor, the third motor, the fourth motor, the fifth motor, the sixth motor, and the seventh motor is a hollow shaft motor.

The cleaning section transfer robot has an effect of allowing the wiring to pass through the inside of the motor as an example.

In addition, the present application discloses, as one embodiment, a substrate processing apparatus further including a wafer station configured to hold the substrate polished by the polishing section, wherein the least one of the one or more cleaning section transfer robots is configured to be able to transfer the substrate accommodated in the wafer station to the at least one of the one or more cleaning modules.

The disclosed content reveals details of the substrate processing apparatus.

In addition, the present application discloses, as one embodiment, a substrate processing apparatus further including a controller, wherein the controller controls the substrate processing apparatus to execute operations of moving the first hand or the second hand not holding the substrate into an inside of the cleaning module in which the substrate is accommodated or into an inside of the wafer station in which the substrate is accommodated by linear movement, receiving the substrate by the first hand or the second hand, and folding the first substrate transfer mechanism or the second substrate transfer mechanism while driving the first motor so that the substrate passes through a track away from an obstacle. Moreover, the present application discloses, as one embodiment, a substrate transfer method using a cleaning section transfer robot, more particularly, a substrate transfer method using a cleaning section transfer robot including the above-described respective operations.

In addition, the present application discloses, as one embodiment, a substrate processing apparatus further including a controller, wherein the controller controls the substrate processing apparatus to execute operations of moving the first hand or the second hand holding the substrate into an inside of the cleaning module or into an inside of the wafer station while driving the first motor so as to pass through a track away from an obstacle, delivering the substrate from the first hand or the second hand, and folding the first substrate transfer mechanism or the second substrate transfer mechanism so that the first hand or the second hand linearly moves. Moreover, the present application discloses, as one embodiment, a substrate transfer method using a cleaning section transfer robot, more particularly, a substrate transfer method using a cleaning section transfer robot including the above-described respective operations.

The substrate processing apparatus and the substrate transfer method have an effect of enabling the transfer of the substrate even when an obstacle is present due to the limitation of the space inside the substrate processing apparatus as an example.

In addition, the present application discloses, as one embodiment, a substrate processing apparatus in which the track through which the substrate passes is determined based on design data of the substrate processing apparatus and a substrate transfer method.

The disclosed content reveals how the track that the substrate needs to pass is determined.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A cleaning section transfer robot for transferring a substrate to and from a cleaning module of a substrate cleaning section of a substrate processing apparatus, the cleaning section transfer robot comprising:
a base;
a rotary table provided on the base;
a first motor configured to rotate the rotary table;
a first substrate holding mechanism, as a first substrate transfer mechanism, the first substrate holding mechanism including:
a second motor provided on the rotary table and having a common rotation axis with the first motor;
a first arm connected to the second motor;
a third motor provided on a tip end of the first arm;
a second arm connected to the third motor;
a fourth motor provided on a tip end of the second arm; and
a first hand connected to the fourth motor to hold the substrate; and
a second substrate holding mechanism, as a second substrate transfer mechanism, the second substrate holding mechanism including:
a fifth motor provided on the first arm and having a common rotation axis with the first motor;
a third arm connected to the fifth motor;
a sixth motor provided on a tip end of the third arm;
a fourth arm connected to the sixth motor;
a seventh motor provided on a tip end of the fourth arm; and
a second hand connected to the seventh motor to hold the substrate,
wherein each of the first arm, the second arm, the third arm, the fourth arm, the first hand, and the second hand extends in a direction perpendicular to the rotation axis of the first motor, and
wherein each of the third motor, the fourth motor, the sixth motor, and the seventh motor has a rotation axis parallel to the rotation axis of the first motor.

2. The cleaning section transfer robot according to claim 1, wherein the first arm, the second arm, the third arm and the fourth arm have the same length.

3. The cleaning section transfer robot according to claim 1, wherein positions of the fifth motor and the third arm in a direction along the rotation axis of the first motor are between a position of the first arm in the direction along the rotation axis of the first motor and a position of the second arm in the direction along the rotation axis of the first motor, and
wherein positions of the second arm, the fourth motor, and the first hand in the direction along the rotation axis of the first motor are between the position of the third arm in the direction along the rotation axis of the first motor and a position of the fourth arm in the direction along the axis of rotation of the first motor.

4. The cleaning section transfer robot according to claim 1, further comprising:
a sensor configured to detect presence or absence of the substrate on the first hand and the second hand.

5. The cleaning section transfer robot according to claim 1, further comprising:
a tray provided on the base to accommodate a liquid.

6. The cleaning section transfer robot according to claim 1, wherein at least one of the first motor, the second motor, the third motor, the fourth motor, the fifth motor, the sixth motor, and the seventh motor is a hollow shaft motor.

7. A substrate processing apparatus comprising:
a polishing section including a polishing pad configured to polish a substrate; and
a substrate cleaning section configured to clean the substrate polished by the polishing section,
wherein the substrate cleaning section includes:
one or more cleaning modules, and
one or more cleaning section transfer robots configured to transfer the substrate to and from at least one of the one or more cleaning modules,
wherein the at least one of the one or more cleaning section transfer robots includes:
a base;
a rotary table provided on the base;
a first motor configured to rotate the rotary table;
a first substrate holding mechanism, as a first substrate transfer mechanism, the first substrate holding mechanism including:
a second motor provided on the rotary table and having a common rotation axis with the first motor;
a first arm connected to the second motor;
a third motor provided on a tip end of the first arm;
a second arm connected to the third motor;
a fourth motor provided on a tip end of the second arm; and
a first hand connected to the fourth motor to hold the substrate; and
a second substrate holding mechanism, as a second substrate transfer mechanism, the second substrate holding mechanism including:
a fifth motor provided on the first arm and having a common rotation axis with the first motor;
a third arm connected to the fifth motor;
a sixth motor provided on a lip end of the third arm;
a fourth arm connected to the sixth motor;
a seventh motor provided on a tip end of the fourth arm; and
a second hand connected to the seventh motor to hold the substrate,
wherein each of the first arm, the second arm, the thud arm, the fourth arm, the first hand, and the second hand extends in a direction perpendicular to the rotation axis of the first motor, and
wherein each of the third motor, the fourth motor, the sixth motor, and the seventh motor has a rotation axis parallel to the rotation axis of the first motor.

8. The substrate processing apparatus according to claim 7, further comprising:
a wafer station configured to hold the substrate polished by the polishing section,
wherein the least one of the one or more cleaning section transfer robots is configured to transfer the substrate accommodated in the wafer station to the at least one of the one or more cleaning modules.

9. The substrate processing apparatus according to claim 8, further comprising:
a controller configured to:
move the first band or the second hand not holding the substrate into an inside of the cleaning module in which the substrate is accommodated or into an inside of the wafer station in which the substrate is accommodated by linear movement;
receive the substrate by the first hand or the second hand; and
fold the first substrate transfer mechanism or the second substrate transfer mechanism while driving the first motor so that the substrate passes through a track away from an obstacle.

10. The substrate processing apparatus according to claim 8, further comprising:
a controller configured to:
move the first hand or the second hand holding the substrate into an inside of the cleaning module or into an inside of the wafer station while driving the first motor so as to pass through a track away from an obstacle;
deliver the substrate from the first hand or the second hand; and
fold the first substrate transfer mechanism or the second substrate transfer mechanism so that the first hand or the second hand linearly moves.

11. The substrate processing apparatus according to claim 9, wherein the track through which the substrate passes is determined based on design data of the substrate processing apparatus.

12. A substrate transfer method using the cleaning section transfer robot in the substrate processing apparatus according to claim 8, the method comprising:
moving the first hand or the second hand not holding the substrate into an inside of the cleaning module in which the substrate is accommodated or into an inside of the wafer station in which the substrate is accommodated by linear movement;
receiving the substrate by the first hand or the second hand; and
folding the first substrate transfer mechanism or the second substrate transfer mechanism while driving the first motor so that the substrate passes through a track away from an obstacle.

13. A substrate transfer method using the cleaning section transfer robot in the substrate processing apparatus according to claim 8, the method comprising;
moving the first hand or the second hand holding the substrate into an inside of the cleaning module or into an inside of the wafer station while driving the first motor so as to pass through a track away from an obstacle;
delivering the substrate from the first hand or the second hand; and
folding the first substrate transfer mechanism or the second substrate transfer mechanism so that the first hand or the second hand linearly moves.

14. The substrate transfer method according to claim 12, wherein the track through which the substrate passes is determined based on design data of the substrate processing apparatus.
